(19) United States
(12) Patent Application Publication
(10) Pub. No.: US 2011/0300673 A1
(43) Pub. Date: Dec. 8, 2011

(54) POST-DISPENSE VACUUM OVEN FOR REDUCING UNDERFILL VOIDS DURING IC ASSEMBLY

(75) Inventors: EMORY TONGOL MERCADO, BAGUIO CITY (PH); EDGARDO HORTALEZA, BAGUIO CITY (PH); JOHN PAUL KWO, BAGUIO CITY (PH)

(73) Assignee: TEXAS INSTRUMENTS INCORPORATED, Dallas, TX (US)

(21) Appl. No.: 12/796,430

(22) Filed: Jun. 8, 2010

(51) Int. Cl. H01L 21/56

(52) U.S. Cl. 438/126; 257/E21.502

(57) ABSTRACT

An IC assembly method for reducing voids in underfill material. An IC die is bonded to a substrate which creates a gap between the IC die and the substrate. An underfill material that has a curing temperature (Tuc) is dispensed around at least one side along a perimeter of the gap, where capillary forces draw the underfill material into the gap to at least partially fill the gap to form an underfilled IC assembly. After the dispensing, a vacuum oven process is applied to the underfilled IC assembly which applies a vacuum of 15 to 140 torr and a temperature that is between Tuc −85° C. and Tuc −5° C., for reducing voids in the underfill material. The underfill material is then cured by heating the underfilled IC assembly to a temperature ≧ Tuc.

### FIELD

Disclosed embodiments relate to integrated circuit (IC) assembly. More particularly, disclosed embodiments relate to the underfill material interposed between an IC device and a substrate.

### BACKGROUND

Semiconductor devices are subject to many competing design goals. Since it is very often desirable to minimize the size of electronic apparatus, surface mount semiconductor devices are often used due to their small footprints. Solder nodules or “bumps” having spherical, near-spherical, or other shapes are frequently used to join an IC to a substrate, such as a printed circuit board (PCB). The IC and substrate have corresponding metallized locations generally known as contact points, or bond pads. The components are aligned, typically using sophisticated optical aligning tools. Solder bumps positioned at the prepared metallized locations are heated, and solder bonds are formed between the contact points upon cooling. When completed, the IC-to-substrate assembly solder joints are typically “blind,” that is, they are not readily accessible for visual inspection. Often the gap between the IC and substrate is filled with a dielectric underfill material. The IC assembly is then generally encapsulated in a protective plastic package in order to in order to provide increased strength and protection.

Among the problems encountered with packaged IC assemblies, some of the most common and debilitating are the separation of layers (i.e., delamination), and open or short circuits caused by separation of materials, or the ingress of moisture between separated materials. For these reasons, void-free underfill processes and materials are desirable. Various combinations of underfill materials, dispensing patterns, and flow techniques have been used in efforts to reduce the formation of voids and reduce underfill process time. Common underfill dispensing techniques include “I” pass dispensing in which a dispensing needle makes one or more passes along one edge of the gap between the die and substrate and the underfill material flows into the gap by capillary action or by the application of vacuum or suction force. Another common underfill dispensing technique is L-dispensing, in which underfill material is dispensed along two adjacent edges of the gap.

Problems persist in the efforts to achieve void-free or substantially void-free underfills while maintaining high throughput. Voids form when the ambient, that is typically air, becomes entrapped by the underfill material while flowing to fill the gap. Most efforts to reduce underfill voiding relate to pre-dispense processing, changes to the underfill dispense process, or developing new underfill materials. However, new underfill assembly processes are still needed to lower voiding while maintaining high throughput.

### SUMMARY

Disclosed embodiments describe IC assembly methods for reducing voids in underfill material that add a vacuum oven process step between the underfill dispense and underfill cure. The temperature is maintained prior to and during vacuum oven processing in a range that ensures that the underfill material maintains its viscosity and flowable state during vacuum oven processing. The Inventors have discovered that the combination of heating to maintain the underfill material's viscosity and flowability and a vacuum in a fairly narrow range of vacuum levels as disclosed herein allows the underfill voids formed during the dispense to migrate out from the gap under the IC die with minimal underfill material resistance which permits underfill flow to fill the evacuated voids. The Inventors have unexpectedly found that void-free or low void underfill results can only be obtained while the underfill is heated to maintain the underfill material's viscosity and flowability using a vacuum level in a range from 15 to 140 torr, with too much vacuum resulting in significant voiding particularly at or near the IC die edges, and too little vacuum again failing to provide the desired void-free or low void underfill results by not significantly reducing the underfill voids present after underfill dispense and subsequent capillary filling of the gap. Significantly, disclosed IC assembly methods provide an inexpensive way (a single short added vacuum oven step) to achieve void-free or at least low void underfill for a wide variety of different underfill materials.

In a typical embodiment, an IC die is bonded to a substrate which creates a gap between the IC die and the substrate. An underfill material that has a curing temperature (Tuc) is dispensed around at least one side along a perimeter of the gap, where capillary forces draw the underfill material into the gap to at least partially fill the gap to form an underfilled IC assembly. After the dispensing, a vacuum oven process is applied to the underfilled IC assembly which comprises applying a vacuum of 15 torr to 140 torr and a temperature (Tvo) that is between Tuc −85° C. and Tuc −5° C. (thus avoiding underfill cure) that fills the voids with flowing underfill to reduce voids in the underfill material. The underfill material is then cured by heating the underfilled IC assembly at a temperature ≧ Tuc.

### BRIEF DESCRIPTION OF THE DRAWING

FIG. 1 is a flow chart that shows steps in an exemplary IC assembly method for reducing voids in underfill material, according to an embodiment of the invention.

### DETAILED DESCRIPTION

Disclosed embodiments in this Disclosure are described with reference to the attached figure. The figures are not drawn to scale and they are provided merely to illustrate the disclosed embodiments. Several aspects are described below with reference to example applications for illustration. It should be understood that numerous specific details, relationships, and methods are set forth to provide a full understanding of the disclosed embodiments. One having ordinary skill in the relevant art, however, will readily recognize that the subject matter disclosed herein can be practiced without one or more of the specific details or with other methods. In other instances, well-known structures or operations are not shown in detail to avoid obscuring structures or operations that are not well-known. This Disclosure is not limited by the illustrated ordering of acts or events, as some acts may occur in different orders and/or concurrently with other acts or events. Furthermore, not all illustrated acts or events are required to implement a methodology in accordance with this Disclosure.

Notwithstanding that the numerical ranges and parameters setting forth the broad scope of this Disclosure are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

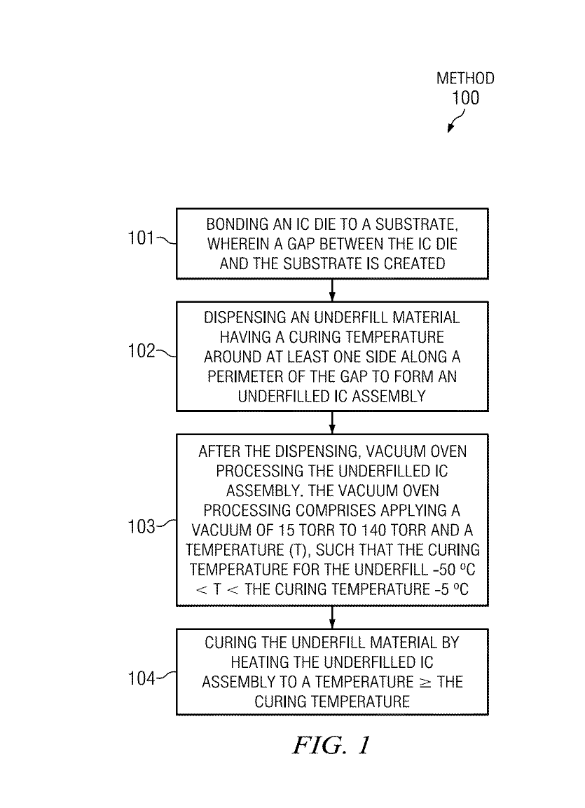

FIG. 1 is a flow chart that shows steps in an exemplary IC assembly method for reducing voids in underfill material, according to a disclosed embodiment. Step 101 comprises bonding an IC die to a substrate. As known in the art, a gap between the IC die and the substrate is created. The substrate can comprise a PCB (organic or ceramic), a wafer, or a Package-on-Package (PoP) precursor such as comprising one or more IC die bonded to a package substrate (e.g. PCB). In one embodiment the substrate comprises a plurality of IC die bonded to a plurality of die areas on the substrate (e.g., substrate panel), for later substrate singulation. The bonding can comprise flip chip bonding, or bonding the IC face (i.e., circuit-side) up, such as when the IC die comprises a through silicon via (TSV) die having a plurality of TSVs.

Step 102 comprises dispensing an underfill material having a curing temperature Tuc around at least one side along a perimeter of the gap to form an underfilled IC assembly. In one embodiment the dispensing comprises vacuum assisted dispensing at a vacuum level of 15 torr (2,000 Pa) to 140 torr (18,664 Pa). The vacuum level selected is generally a function of the IC die size and underfill material viscosity, with a typical minimum pressure of 30 torr (4,000 Pa) and a typical maximum pressure of 110 torr (14,300 Pa). In another embodiment, the underfill dispense is a conventional atmospheric pressure dispense.

As known in the art, capillary forces draw the underfill material into the gap to substantially fill the gap. However, the ambient (typically air) becomes entrapped by the flowing underflow material during the capillary action to fill the gap that results in the formation of underfill voids, that using conventional subsequent processing remain present through underfill cure and are thus present in the final IC assembly. The underfill material can comprise a thermosetting polymer, such as an epoxy, or other suitable curable material. A typical Tuc is from 140° C. to 250° C.

Step 103 comprises, after the dispensing step, vacuum oven processing the underfilled IC assembly. The vacuum oven processing comprises applying a vacuum of 15 torr (2,000 Pa) to 140 torr (18,664 Pa) and a temperature Tvo that is >Tuc −85° C. and <Tuc −5° C. In this temperature range for Tvo, underfill flow is provided to fill underfill voids, while underfill cure is avoided.

In some embodiments the vacuum during vacuum oven processing is at a pressure in a range from 30 torr to 110 torr. The time for the vacuum oven processing is typically at least 15 seconds, such as 15 to 60 seconds, with a time 40 to 45 seconds in one particular embodiment. The time for vacuum oven processing is generally selected based on the size of the IC die. When referring to the time herein for vacuum oven processing, it is the overall process time inside the vacuum oven chamber at the process temperature Tvo. In a typical embodiment the vacuum chamber is maintained at some predetermined Tvo, such as 100° C. for an underfill material having a Tuc between 155° C. and 170° C.

No ramp time for reaching Tvo during vacuum oven processing is needed for heating methods such as infrared (IR) which can control Tvo within a range of +/−10° C. In one particular embodiment, a vacuum ramp time of 10 to 20 seconds is used, such as 15 seconds for the vacuum to reach its target pressure, for example, 30 to 110 torr. The Inventors have discovered that the vacuum ramp time while at Tvo allows the underfill material to maintain its molecular stability and viscosity without inducing excessive material backflow caused by the void migrating movement towards the edge of the IC die. After the vacuum ramp time, the target vacuum inside the vacuum oven chamber is generally maintained, such as for 5 to 15 seconds to allow all possible void sizes in the underfill material to migrate out from under the IC die. A final vacuum venting time (to reach atmospheric pressure to permit unloading) can be included of at least 3 seconds, such as 4 to 6 seconds, to avoid the underfill material collapsing too fast that can cause underfill material over the IC die which is usually a reject criteria for underfill processes. As demonstrated in the Examples below, the vacuum oven processing as disclosed herein significantly reduces voids in the underfill material.

Step 104 comprises curing the underfill material by heating the underfilled IC assembly to a temperature ≧ Tuc to cure the underfill material. As recognized by one having ordinary skill in the art, all steps in method 100 can be implemented as batch processes.

In one embodiment the temperature during dispensing (step 102) the underfill material is at a dispense temperature that is within 10° C. of Tvo. In another embodiment, the temperature during dispensing the underfill material can be the same temperature as Tvo. In one particular embodiment the vacuum oven process parameters comprise a vacuum of about 30 torr to 110 Torr, and Tvo=100 to 110° C. for 30 to 40 seconds for an underfill material that has a Tuc of 155 to 170° C.

The vacuum oven processing can be in-line with the dispensing of the underfill material. An in-line arrangement is defined herein when the vacuum oven is incorporated in the underfill process machine line and is thus placed in the vacuum oven after underfill dispense before being unloaded by an unloader machine. This arrangement allows the temperature and vacuum conditions during underfill dispense to be maintained during vacuum oven processing if desired.

In other embodiments, the vacuum oven processing is off-line with respect to the dispensing of the underfill material. In the off-line embodiment, following underfill dispense, an unloading operation takes place to unload underfilled IC assemblies from the underfill process machine and a loading operation occurs to place the underfilled IC assemblies into the vacuum oven machine. In this arrangement the vacuum oven machine can be designed as an independent machine flexible enough to be added as an upgrade to existing underfill dispensing machines without impacting performance of the underfill dispensing machine.

Disclosed embodiments can be integrated into a variety of assembly flows to form a variety of different IC devices and related products. The IC assembly can comprise single IC die or multiple IC die, such as PoP configurations comprising a plurality of stacked IC die. A variety of package substrates may be used. The IC die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the IC die can formed from a variety of processes including bipolar, CMOS, BiCMOS and MEMS.

### Examples

Disclosed embodiments are further illustrated by the following specific Examples, which should not be construed as limiting the scope or content of this Disclosure in any way.

The Inventors ran a series of experiments with a plurality of different epoxy-based underfill materials including HITACHI P6™ (cure temp 168° C.), HENKEL FP4549™ (cure temp 168° C.), ABLESTIK™ (cure temp 158° C.), NAMICS™ (cure temp 150° C.), first using a baseline assembly flow. The baseline assembly flow comprised a substrate bake at 125° C.+/−5° C. for 4 hours for organic PCB substrates, while ceramic (e.g., HiCTE) PCB substrates did not generally undergo substrate baking. IC die placement and reflow conditions comprised a die placement pressure of 2 to 3 Newtons, die attach reflow conditions of 230° C.+/−5° C. for SnPb solder, and 250° C.+/−5° C. for Pb-Free solder. The capillary underfill comprised a substrate temperature during underfill dispense of 105° C.+/−5° C., a preheat time 105 to 115 seconds at temperature of 110° C.+/−5° C., a post heat time of 180 seconds minimum at temperature of 110° C.+/−5° C. The underfill cure temperature was based on the Tuc for the respective underfill materials. For HITACHI P6™ a cure temp of 168° C. at 90 min minimum, 30 min ramp up/down minimum, 180+/−10 min soak time was used; for HENKEL FP4549™ a cure temp 168° C. at 120 min minimum, 30 min ramp up/down minimum, 60+/−10 min soak time as used; for ABLESTIK™ a cure temp of 158° C. at 90 min minimum, 30 min ramp up/down minimum, 180+/−10 min soak time, was used, and for and for NAMICS™ a cure temp of 150° C. at 120 min minimum, 30 min ramp up/down minimum, 60+/−10 min soak time was used.

An assembly flow according to a disclosed embodiment comprised the baseline flow parameters described above modified to add vacuum oven processing between the underfill dispense and underfill cure. The vacuum oven processing comprised 100° C. at a vacuum of about 100 torr for 30 seconds (vacuum ramp time of 15 seconds used as the ramp time for the vacuum to reach its target pressure of 100 torr, 10 seconds to allow all possible void sizes in the underfill material to migrate out from under the IC die, and a final vacuum venting time (to reach atmospheric pressure to permit unloading of 5 seconds). As described above, the final vacuum venting time is generally included to avoid underfill material collapsing too fast that can cause underfill material over the die.

A Scanning Acoustic Microscopy (SAM) machine was used to measure the underfill voids present in the underfill after underfill cure. The baseline flow resulted in microvoids and scattered voids detected after underfill cure. This is currently seen on typical flip chip IC devices which may have at least one of the following root cause excessive flux (residual flux), substrate moisture out-gassing, underfill material volatiles out-gassing, IC bump design layout (underfill material desired flow may be slower on some parts of the IC which causes air pockets to form within the IC). The baseline flow modified to add vacuum oven processing between capillary underfill and underfill cure resulted in no delamination and zero voids (no microvoids and scattered voids) detected after underfill cure for a total of 48 units tested.

While various disclosed embodiments have been described above, it should be understood that they have been presented by way of example only, and not limitation. Numerous changes to the subject matter disclosed herein can be made in accordance with this Disclosure without departing from the spirit or scope of this Disclosure. In addition, while a particular feature may have been disclosed with respect to only one of several implementations, such feature may be combined with one or more other features of the other implementations as may be desired and advantageous for any given or particular application.

Thus, the breadth and scope of the subject matter provided in this Disclosure should not be limited by any of the above explicitly described embodiments. Rather, the scope of this Disclosure should be defined in accordance with the following claims and their equivalents.

The terminology used herein is for the purpose of describing particular embodiments only and is not intended to be limiting. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which embodiments of the invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

We claim:

1. An IC assembly method for reducing voids in underfill material, comprising:
bonding an IC die to a substrate, wherein a gap between said IC die and said substrate is created;
dispensing an underfill material having a curing temperature (Tuc) around at least one side along a perimeter of said gap, wherein capillary forces draw said underfill material into said gap to at least partially fill said gap to form an underfilled IC assembly;
after said dispensing, vacuum oven processing said underfilled IC assembly, said vacuum oven processing comprising applying a vacuum of 15 torr to 140 torr and a temperature (Tvo) that is between said Tuc −85° C. and said Tuc −5° C., for reducing said voids in said underfill material, and
curing said underfill material by heating said underfilled IC assembly at a temperature ≧ said Tuc to cure said underfill material.

2. The method of claim 1, wherein said bonding comprises flip chip bonding said IC die to said substrate.

3. The method of claim 1, wherein said substrate comprises an organic printed circuit board (PCB).

4. The method of claim 1, wherein said bonding comprises face-up bonding said IC die to said substrate.

5. The method of claim 4, wherein said IC die comprises a through silicon via (TSV) die.

6. The method of claim 1, wherein said dispensing said underfill material comprises vacuum assisted dispensing at a vacuum level of 15 torr to 140 torr.

7. The method of claim 1, wherein said vacuum during said vacuum oven processing is 30 to 110 torr.

8. The method of claim 1, wherein a temperature during said dispensing said underfill material is at a dispense temperature, and said Tvo is within 10° C. of said dispense temperature.

9. The method of claim 1, wherein said vacuum oven processing is in-line with said dispensing said underfill material.

10. The method of claim 1, wherein said vacuum oven processing is off-line with respect to said dispensing said underfill material.

11. The method of claim 1, wherein a time for said vacuum oven processing is at least 20 seconds.

12. The method of claim 1, wherein said time for said vacuum oven processing includes a final vacuum venting time of at least 3 seconds to release said vacuum to reach an atmospheric pressure.

13. An IC assembly method for reducing voids in underfill material, comprising:
flip chip bonding an IC die to a substrate, wherein a gap between said IC die and said substrate is created;
dispensing an underfill material having a curing temperature (Tuc) around at least one side along a perimeter of said gap, wherein capillary forces draw said underfill material into said gap to at least partially fill said gap to form an underfilled IC assembly;
after said dispensing, vacuum oven processing said underfilled IC assembly, said vacuum oven processing comprising applying a vacuum of 15 torr to 140 torr and a temperature (Tvo) that is between said curing temperature −85° C. and said curing temperature −5° C., for reducing said voids in said underfill material, and curing said underfill material by heating said underfilled IC assembly at a temperature ≧ said Tuc to cure said underfill material.

14. The method of claim 13, wherein said dispensing said underfill material comprises vacuum assisted dispensing at a vacuum level of 15 torr to 140 torr.

15. The method of claim 13, wherein said vacuum during said vacuum oven processing is from 30 torr to 100 torr.

16. The method of claim 13, wherein a temperature during said dispensing said underfill material is at a dispense temperature, and said temperature during said vacuum oven processing is within 10° C. of said dispense temperature.

17. The method of claim 13, wherein said vacuum oven processing is in-line with said dispensing said underfill material.

18. The method of claim 13, wherein said substrate comprises an organic printed circuit board (PCB).
